(19) United States
(12) Patent Application Publication
(10) Pub. No.: US 2026/0096272 A1
(43) Pub. Date: Apr. 2, 2026

(54) DISPLAY DEVICE

(71) Applicant: AUO Corporation, Hsinchu City (TW)

(72) Inventors: Ken Ching Lin, Hsinchu City (TW); Chao-Wei Huang, Hsinchu City (TW)

(73) Assignee: AUO Corporation, Hsinchu City (TW)

(21) Appl. No.: 18/967,593

(22) Filed: Dec. 3, 2024

(30) Foreign Application Priority Data
Sep. 27, 2024 (TW) 113137087

(51) Int. Cl. H10H 29/853; H10H 29/01; H10H 29/24; H10H 29/85

(52) U.S. Cl. CPC H10H 29/853; H10H 29/012; H10H 29/0362; H10H 29/24; H10H 29/8506

(57) ABSTRACT

A display device includes a substrate, a light-emitting element, and an encapsulation layer. The light-emitting element is disposed on the substrate, the encapsulation layer is disposed on the substrate and covers the light-emitting element, the light-emitting element has a first width in a first direction, the encapsulation layer has a top surface, the top surface includes a first trench, the first trench has a second width in the first direction, and the second width is greater than the first width.

### CROSS-REFERENCE TO RELATED APPLICATION

This application claims the priority benefit of Taiwan application serial no. 113137087, filed on Sep. 27, 2024. The entirety of the above-mentioned patent application is hereby incorporated by reference herein and made a part of this specification.

### BACKGROUND

### Technical Field

This disclosure relates to a display device.

### Description of Related Art

In the current design of manufacturing processes for light-emitting element, when defects occur, it is necessary to remove the blocking layer and the optical adhesive layer surrounding the light-emitting element, as well as the black matrix and the optical element layer above, and then re-set the optical element. However, if only the optical adhesive layer is backfilled, light leakage may occur due to insufficient adhesion between the black matrix and the optical element layer of the light-emitting device, resulting in insufficient brightness of the display device. As a result, it may be important to avoid the above problem.

### SUMMARY

The disclosure provides a display device with good brightness and display performance.

The disclosure display device includes a substrate, a light-emitting element, and an encapsulation layer. The light-emitting element is disposed on the substrate. The encapsulation layer is disposed on the substrate and covers the light-emitting element. The light-emitting element has a first width in a first direction. The encapsulation layer has a top surface. The top surface includes a first trench. The first trench has a second width in the first direction, and the second width is greater than the first width.

Based on the above, in the display device of the disclosure, the top surface of the encapsulation layer has a first trench, the light-emitting element has a first width in the first direction, the first trench has a second width in the first direction D1, and the second width is greater than the first width. In this way, when the light-emitting element emits light, since the second width of the first trench is larger than the first width of the light-emitting element, the problem of light leakage from the display device may be effectively solved and good brightness and display performance may be maintained.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate example embodiments of the disclosure and, together with the description, serve to explain the principles of the disclosure.

FIG. 1A to FIG. 1F are schematic cross-sectional views of part of the process of manufacturing a display device according to an embodiment of the disclosure.

FIG. 2A is a partially enlarged cross-sectional view of an area A in FIG. 1D.

FIG. 2B is a partially enlarged top view of an area A in FIG. 1E.

### DESCRIPTION OF THE EMBODIMENTS

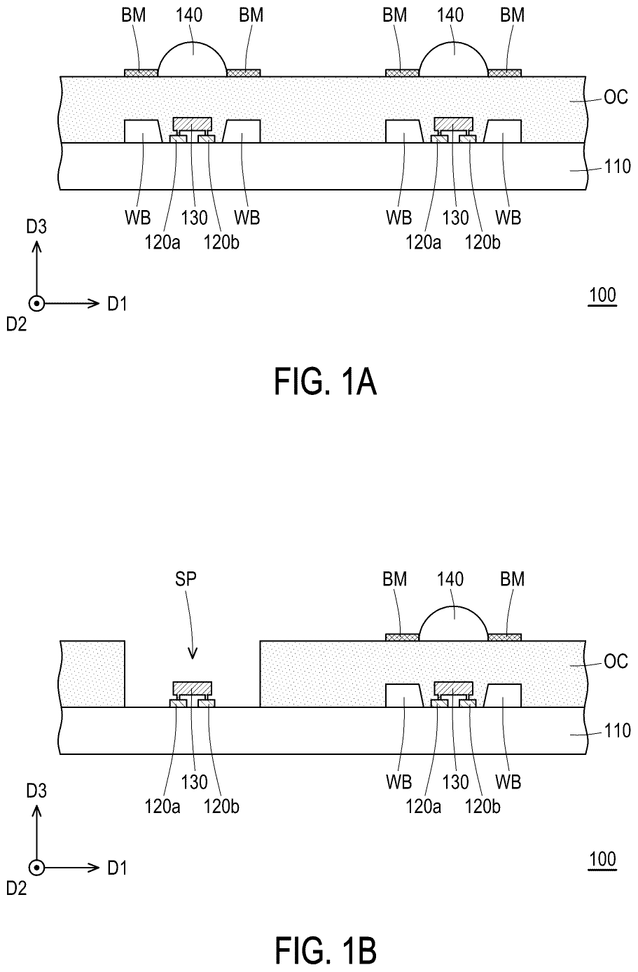

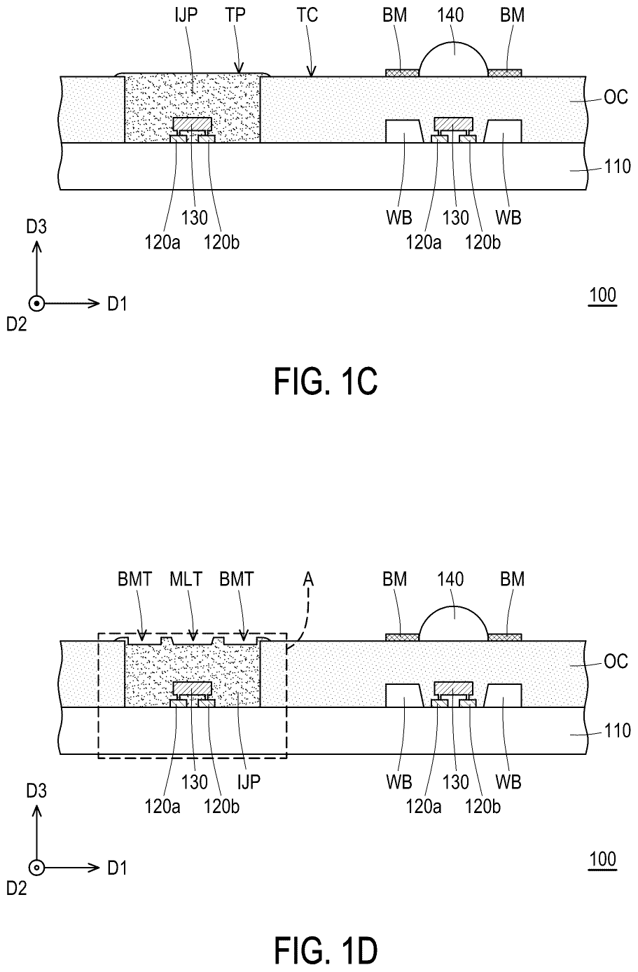

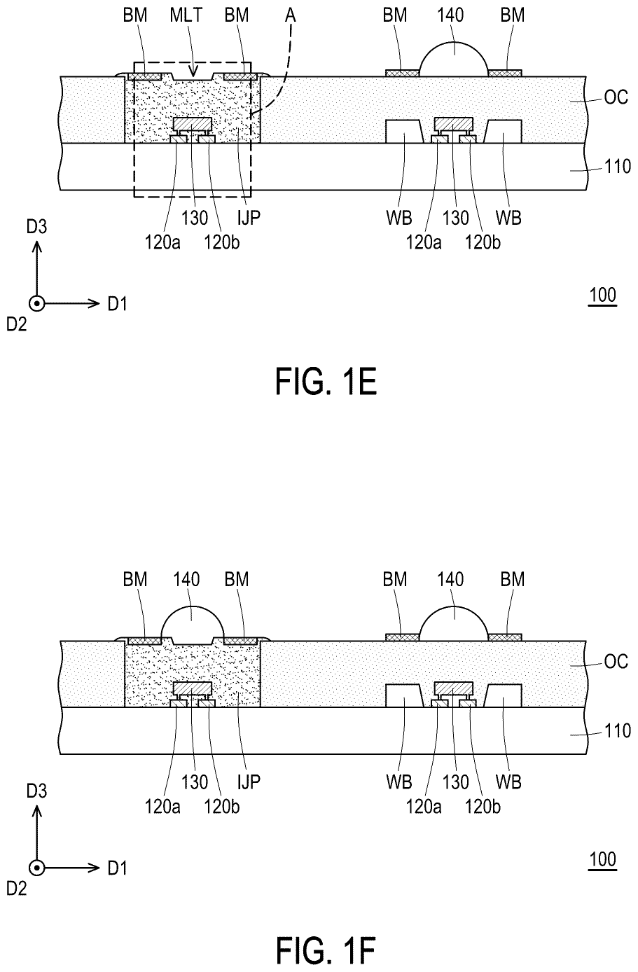

FIG. 1A is a schematic cross-sectional view of part of the process of manufacturing a display device according to an embodiment of the disclosure. As shown in FIG. 1A, a display device 100 includes a substrate 110, and light-emitting elements 130 are formed on the substrate 110. The material of the substrate 110 may be a plate-like object that has supporting properties and can reduce bending, wrinkles and/or deformation of the substrate 110. For example, the material of the substrate 110 may include glass, quartz, or other suitable materials, or a combination of the above materials, but the disclosure is not limited thereto. The substrate 110 may be solidified from a liquid and/or gel-like initial material. In some embodiments, the method of forming the substrate 110 includes coating a liquid and/or gel-like initial material on the substrate 110, and then using a curing process to solidify the liquid and/or gel-like initial material to form the flexible substrate 110, in which the curing process that can be used includes thermal curing, light curing, or a combination of the above curing processes, but the disclosure is not limited thereto. The material of the substrate 110 may include, but is not limited to, a single-layer structure of polyimide (PI), polyethylene terephthalate (PET), or one of the other applicable materials, or a stack or blend of at least two of the foregoing materials. In other words, the flexible substrate 110 may be a single-layer substrate or a multi-layer substrate composed of multiple layers stacked.

Electrodes 120a and 120b, the light-emitting elements 130 and blocking layers WB are sequentially formed on the substrate 110. An optical adhesive layer OC directly contacts and covers the substrate 110, the blocking layers WB, and the light-emitting elements 130 on the substrate 110. Optical element layers 140 are formed on the optical adhesive layer OC and overlap the light-emitting elements 130 in the normal direction of the substrate 110, and black matrixes BM surrounds the optical element layers 140 and contacts the optical element layers 140. In this way, when the light-emitting elements 130 emit light, the light is emitted from the optical element layers 140 and the black matrixes BM contacts the optical element layers 140, which may block light leakage and improve luminous efficiency of the display device 100. The optical element layer 140 may be, for example, a lens layer, such as a convex lens layer, but is not limited thereto. In this embodiment, after the display device 100 is manufactured, the substrate 110 may include multiple light-emitting elements 130 at the same time, and the multiple light-emitting elements 130 may be arranged in a first direction D1 or a second direction D2, but is not limited thereto.

In some embodiments, the light-emitting element 130 may include, for example, an organic light-emitting diode (OLED), a sub-millimeter light-emitting diode (mini LED), a micro-light-emitting diode (micro LED), or a quantum dot (QD) LED (e.g., QLED, QDLED), fluorescence, phosphor, or other suitable materials, and the materials thereof can be arbitrarily arranged and combined, but are not limited thereto. The blocking layer WB is disposed around the light-emitting element 130, and the blocking layer WB may include a multi-layer structure, such as a two-layer structure, but the disclosure is not limited thereto and may also be a single-layer structure. In addition, the optical adhesive layer OC can cover the entire surface of the substrate 110 to increase the barrier effect against the water and oxygen.

FIG. 1B is a schematic cross-sectional view of part of the process of manufacturing a display device according to an embodiment of the disclosure. As shown in FIG. 1B, when the light-emitting element 130 on the substrate 110 encounters a malfunction, a contact hole SP is first formed on the optical adhesive layer OC. The position of the contact hole SP roughly corresponds to the position of a single light-emitting element 130 on the substrate 110 and the width of the contact hole SP in the first direction D1 is greater than the width of the light-emitting element 130 in the first direction, but the contact hole SP overlaps the light-emitting element 130 in the normal direction of the substrate 110. In some embodiments, the contact hole SP may extend to the position of another light-emitting element 130 to simultaneously address malfunction conditions of two or more light-emitting elements 130, but is not limited thereto. In some embodiments, the design of the contact hole SP can be patterned and distributed in designated areas, but the disclosure is not limited thereto. The contact hole SP is patterned to at least partially correspond to the light-emitting element 130. For example, the orthographic projection of the pattern of the contact holes SP on the substrate 110 may overlap the orthographic projection of the pattern of the light-emitting element 130 on the substrate 110.

After the contact hole SP is formed, the blocking layer WB and the faulty light-emitting element 130 are removed and another non-faulty light-emitting element 130 is connected to the electrodes 120a and 120b. Referring to FIG. 1C, an encapsulation layer IJP is formed in the contact hole SP. The encapsulation layer IJP extends in the first direction D1 and partially covers a top surface TC of the transparent adhesive layer OC, so as to increase the barrier effect against the water and oxygen on the light-emitting element 130, and to enhance the luminous efficiency of the display device 100.

Inkjet printing technology is used for the formation of the encapsulation layer IJP, which utilizes tiny ink droplets to accurately position the area to be coated. In this embodiment, by using inkjet printing technology and appropriate inkjet materials, the encapsulation layer IJP can be completely formed inside the contact hole SP and partially cover the top surface TC of the optical adhesive layer OC. In some embodiments, the surface tension value of the inkjet material ranges, for example, from 20 to 35 milli-Newtons per meter (mN/m), but is not limited thereto.

Referring to FIG. 1D, the encapsulation layer IJP has a top surface TP. Laser etching technology is used to form a trench MLT and trenches BMT on the top surface TP. The trenches BMT are disposed around the trench MLT and the trench MLT and the trenches BMT are not connected to each other. The trench MLT overlaps the light-emitting element 130 in the normal direction of the substrate 110.

Next, referring to FIG. 1E and FIG. 1F, black matrixes BM are formed in the trenches BMT and the optical element layer 140 is formed on the trench MLT. The optical element layer 140 completely covers the trench BMT. The optical element layer 140 overlaps the light-emitting element 130 in the normal direction of the substrate 110. The black matrixes BM surrounds the optical element layer 140. The black matrix BM may block light leakage so that the light emitted by the light-emitting element 130 is completely emitted by the optical element layer 140, enhancing the luminous efficiency of the display device 100.

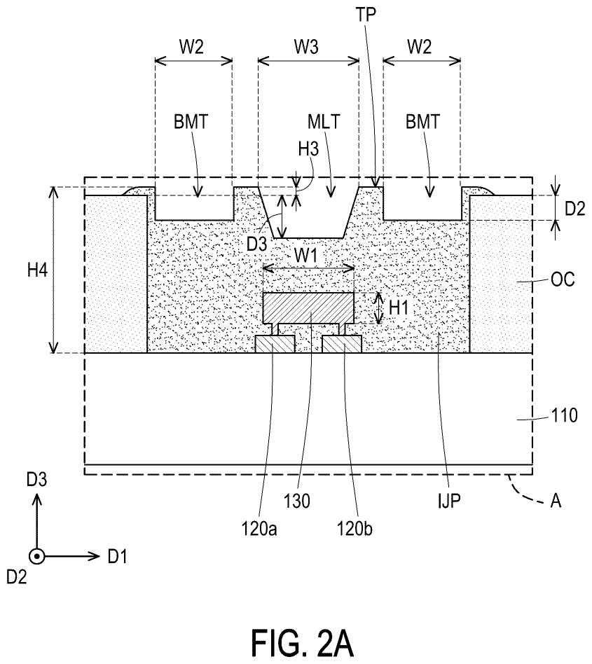

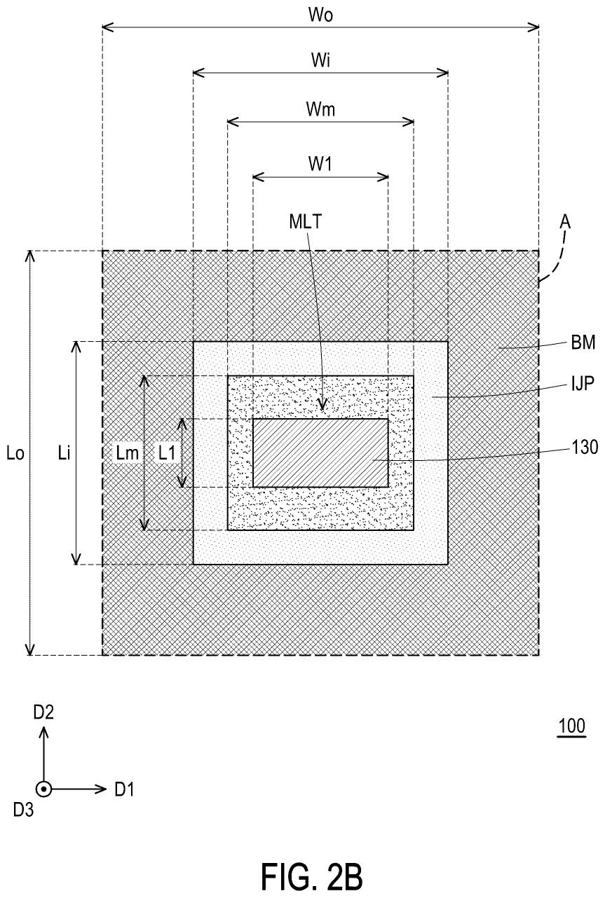

FIG. 2A is a partially enlarged cross-sectional view of an area A in FIG. 1D. FIG. 2B is a partially enlarged top view of an area A in FIG. 1E.

Please refer to FIG. 2A and FIG. 2B at the same time. The light-emitting element 130 has a width W1 in the first direction D1, a length L1 in the second direction, and a height H3 between the bottom surface and the top surface of the light-emitting element in a third direction D3. The ratio of the length L1 to the width W1 of the light-emitting element 130 ranges from, for example, 20:40, 15:30, or 13:28. From a top view perspective, the trench MLT has a width Wm in the first direction and a length Lm in the second direction D2. The width Wm of the trench MLT in the first direction is about 5 microns more than the width W1 of the light-emitting element 130 in the first direction, i.e., the width Wm of the trench MLT is greater than the width W1 of the light-emitting element 130. A depth D3 of the trench MLT can be defined in the third direction D3 between the bottom surface of the trench MLT and the top surface TC of the optical adhesive layer OC, and the depth D3 of the trench MLT ranges, for example, from 10 to 15 microns. The top surface TP of the trench MLT has a height H3 relative to the top surface TC of the optical adhesive layer OC in the third direction D3, and the height H3 ranges, for example, from 5 to 10 microns.

Please refer to FIG. 2B. From a top view perspective, the trench BMT forms a shape of an overlapping small square and big square. The inner frame of the trench BMT has a width Wi in the first direction D1, and the inner frame of the trench BMT has a length Li in the second direction D2. The width Wi of the trench BMT in the first direction is about 10 microns more than the width W1 of the light-emitting element 130 in the first direction. The ratio of the length Li to the width W1 of the trench BMT is, for example, 60:60. The outer frame of the trench BMT has a width Wo in the first direction D1, and the outer frame of the trench BMT has a length Lo in the second direction D2. The ratio of the length Lo to the width Wo of the trench BMT ranges, for example, from 100:100 to 150:150. A depth D2 of the trench BMT can be defined in the third direction D3 between the bottom surface of the trench BMT and the top surface TC of the optical adhesive layer OC, and the depth D2 of the trench BMT can range, for example, from 5 to microns. The top surface TP of the encapsulation layer IJP and the top surface of the substrate 110 have a height H4 in the third direction D3. In some implementations, the sum of the depth D2, the depth D3, and the height H3 is less than the height H4 of the encapsulation layer IJP. In this way, through the design of the size parameters of any of the trench BMT, the trench MLT, and the light-emitting element 130, the optical element layer 140 and the black matrix BM can be well disposed on the light-emitting element 130, which effectively helps the display device 100 improve the display performance while avoiding light leakage problems.

To sum up, in the display device of the disclosure, the top surface of the encapsulation layer has a first trench, the light-emitting element has a first width in the first direction, the first trench has a second width in the first direction D1, and the second width is greater than the first width. In this way, when the light-emitting element emits light, since the second width of the first trench is larger than the first width of the light-emitting element, the problem of light leakage from the display device may be effectively solved and good brightness and display performance may be maintained.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A display device, comprising:
a substrate;
a light-emitting element, disposed on the substrate; and
an encapsulation layer, disposed on the substrate and covering the light-emitting element,
wherein the light-emitting element has a first width in a first direction, the encapsulation layer has a top surface, the top surface comprises a first trench, the first trench has a second width in the first direction, and the second width is greater than the first width.

2. The display device according to claim 1, wherein the first trench overlaps the light-emitting element in a normal direction of the substrate.

3. The display device according to claim 1, further comprising a second trench, wherein the second trench is disposed around the first trench, the first trench has a first depth in a third direction, the second trench has a second depth in the third direction, and the second depth is less than the first depth.

4. The display device according to claim 1, further comprising a transparent adhesive layer disposed on the substrate, the encapsulation layer extending in the first direction and partially covering a top surface of the transparent adhesive layer.

5. The display device according to claim 1, further comprising a first electrode connected to the light-emitting element, the first electrode overlapping the first trench in a normal direction of the substrate.

6. The display device according to claim 1, further comprising a second trench and a black matrix, the black matrix being disposed in the second trench and the second trench being disposed around the first trench.

7. The display device according to claim 1, further comprising an optical element layer, the optical element layer being disposed on the first trench and covering the first trench.

8. The display device according to claim 7, wherein the optical element layer, the first trench, and the light-emitting element overlap in a normal direction of the substrate.
